(19) United States
(12) Patent Application Publication
(10) Pub. No.: US 2014/0098476 A1
(43) Pub. Date: Apr. 10, 2014

(54) ELECTRONIC DEVICE COVER

(71) Applicants: John R. Severson, Minnetonka, MN (US); James B. Easley, Orono, MN (US)

(72) Inventors: John R. Severson, Minnetonka, MN (US); James B. Easley, Orono, MN (US)

(21) Appl. No.: 14/049,746

(22) Filed: Oct. 9, 2013

Related U.S. Application Data
(60) Provisional application No. 61/711,449, filed on Oct. 9, 2012.

(51) Int. Cl. H05K 5/03

(52) U.S. Cl. CPC H05K 5/03
USPC 361/679.01

(57) ABSTRACT

A protective cover assembly having a tray having a concave surface and a perimeter, the concave surface defining a volume sufficient to accommodate a portable electronic device; and an elastomeric collar having an internal rim that reversibly engages and wraps around the perimeter of the tray.

### CROSS-REFERENCE TO RELATED APPLICATIONS

This utility application claims priority to provisional application No. 61/711449 filed on Oct. 9, 2012, the entire contents of which are incorporated by reference.

### STATEMENT REGARDING FEDERALLY SPONSORED RESEARCH

Not applicable

### TECHNICAL FIELD

This disclosure relates to protective covers for electronic devices. More specifically, the disclosure describes a cover that provides protection for a portable electronic device while allowing access to the interface of the electronic device.

### BACKGROUND OF THE INVENTION

Portable electronic devices often encounter rough handling that could damage the device. For example, the device may be subjected to jarring impact, dust, and liquid. It is well known in the art to protect a portable electronic device by enclosing the device within a protective shell or sleeve.

Generally, users interact with a portable electronic device through a keyboard or touch screen interface. Ideally, protective covers would protect the device while allowing continued user access to the electronic device.

In some instances, it is desirable to restrict user access to particular regions of the device interface. For example, a parent may want to restrict a child from accessing certain features of the device while allowing the child to still use the device.

In light of the above, a need exists to provide an electronic device protective cover that enables restricted or unrestricted access to the device while protecting the device from damage.

### BRIEF SUMMARY OF THE INVENTION

In general, this disclosure describes a protective cover for an electronic device. In some embodiments, the cover protects the device while allowing user access to the device interface. In some embodiments, the cover includes a removable keyguard that can limit touch access to portions of the device. In some embodiments, the protective cover accommodates modules that interface with the enclosed electronic device.

The details of one or more aspects of the disclosure are set forth in the accompanying drawings and the description below. Other features, objects, and advantages will be apparent from the description and drawings, and from the claims.

### BRIEF DESCRIPTION OF THE SEVERAL VIEWS OF THE DRAWINGS

FIG. 1 is a partial cutaway view of an embodiment of the protective cover.

FIG. 2 is a partial cutaway view of an embodiment of the elastomeric collar.

FIG. 3 is a partial cutaway view of the elastomeric collar of FIG. 2 with an electronic device enclosed therein.

FIG. 4 is a top view of an embodiment of the protective tray.

FIG. 5 is a bottom view of an embodiment of the protective cover with an electronic device enclosed therein.

FIG. 6 is a bottom view of an embodiment of the protective cover with an optional module attached thereto.

FIG. 7 is a bottom view of an embodiment showing the plurality of bumpers which suspend the electronic device above the tray, and provide a cushioning effect upon impact.

### DETAILED DESCRIPTION OF THE INVENTION

While this invention may be embodied in many different forms, there are described in detail herein specific examples of the invention. This description is an exemplification of the principles of the invention and is not intended to limit the invention to the particular examples illustrated.

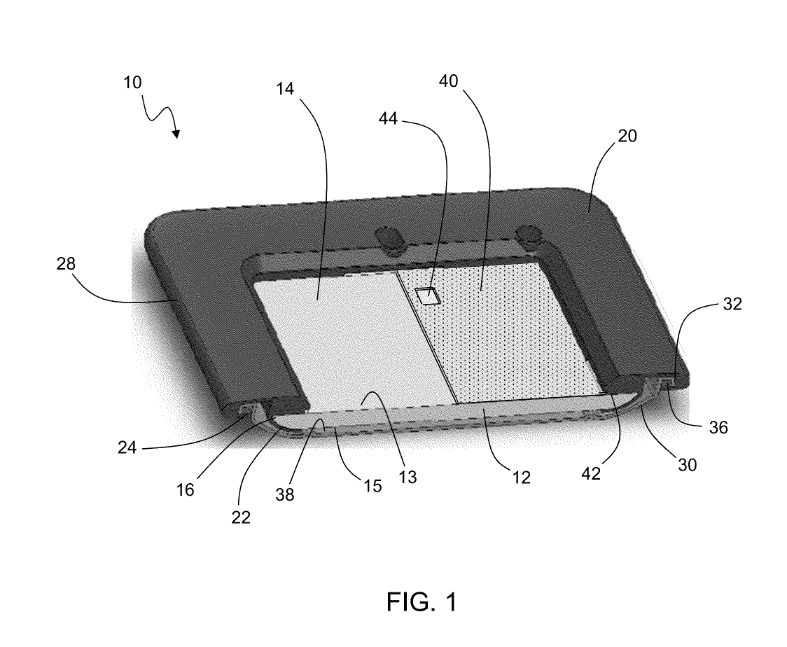

Referring to the figures, FIG. 1 depicts a cutaway view of one embodiment of the inventive protective cover assembly 10. In FIG. 1, protective cover assembly 10 encloses a portable electronic device 12. The dimensions and design of protective cover assembly 10 are easily modified to accommodate a variety of portable electronic devices 12. For example, protective cover assembly 10 may be constructed to encase various models of cell phones, smartphones, tablets, notebooks, MP3 players, and other such similar electronic devices.

Protective cover assembly 10 includes a protective tray 30 and an elastomeric collar 20. In some embodiments protective cover assembly 10 includes a keyguard 40 that covers at least a portion of the interface 14 of the enclosed portable electronic device 12. The dimensions of elastomeric collar 20, protective tray 30, and keyguard 40 are selected to accommodate the dimensions of the portable electronic device 12 that is desired to be enclosed by protective cover assembly 10.

Elastomeric collar 20 is made of a distensible material and wraps around the perimeter 32 of protective tray 30. In this way, elastomeric collar 20 secures the entire enclosure together by acting as a perimeter clamp. In some embodiments, perimeter 32 of protective tray 30 is “C”- or “U”-shaped, providing a groove-like feature 36 that mates with a flap 24 of elastomeric collar 20. In another embodiment, perimeter 32 of protective tray 30 is “L”-shaped and mates with a slit (not shown) of elastomeric collar 20.

A rim portion 28 of elastomeric collar 20 overlays the perimeter 32 of protective tray 30. Rim portion 28 and perimeter 32 of protective tray 30 serve as a bumper that protects portable electronic device 12 from impact. In some embodiments, the rim portion 28 of elastomeric collar 20 is thickened to enhance impact protection.

The enclosed portable electronic device 12 has an edge 16 located intermediate and adjacent to a front aspect 13 and a rear aspect 15 of portable electronic device 12. In some embodiments, elastomeric collar 20 comprises a sleeve 22 that engages at least a portion of edge 16 of portable electronic device 12. In some embodiments, sleeve 22 overlays at least a portion of both front aspect 13 and rear aspect 15. In this way, sleeve 22 captures and suspends portable electronic device 12, providing impact protection by creating a gap between the rear aspect 15 of portable electronic device 12 and interior surface 38 of protective tray 30.

Referring to FIG. 1, some embodiments of the protective cover assembly 10 include a keyguard 40 that overlays at least a portion of the interface 14 of the portable electronic device 12. In at least one embodiment, keyguard 40 is made of a transparent material that permits viewing of interface 14. In at least one embodiment, keyguard 40 is a flat piece of clear plastic that is sufficiently thick to block a user from accessing the portion of interface 14 that is covered by keyguard 40.

In some embodiments, keyguard 40 defines at least one hole 44 that permits access to a localized region of interface 14. In at least one embodiment, keyguard 40 comprises a plurality of holes 44. In some embodiments, the placement of holes 44 within keyguard 40 is selected so that hole 44 provides access to a specific and predictable region of interface 14 of the enclosed portable electronic device 12. In such embodiments, placement of hole 44 within keyguard 40 depends on the anticipated enclosed portable electronic device 12, or on the anticipated software application being run on the enclosed portable electronic device, or on a combination of these factors.

At least a portion of the perimeter of keyguard 40 defines a lip region 42 that secures keyguard 40 to elastomeric collar 20. In some embodiments, keyguard 40 is held in place by sliding lip region 42 between the elastomeric collar 20 and the front aspect 13 of portable electronic device 12. Fixing keyguard 40 to elastomeric collar 20 is merely a design choice, and there are many ways by which keyguard 40 could be held in place. For example, some embodiments of elastomeric collar 20 have recesses (not shown) that accommodate coordinating tabs (not shown) on the lip region 42 of keyguard 40. In this way, keyguard 42 is easily captured by elastomeric collar 20. Similarly, keyguard 42 can be easily removed or changed. In some embodiments, inserting or removing keyguard 40 simply involves pushing elastomeric collar 20 slightly out of shape to lift out keyguard 40 and insert another keyguard 40 of a different design.

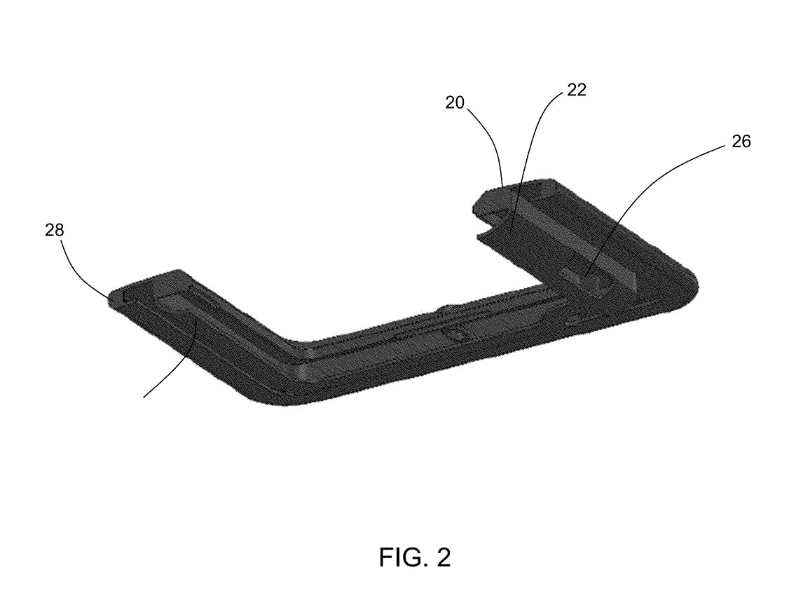

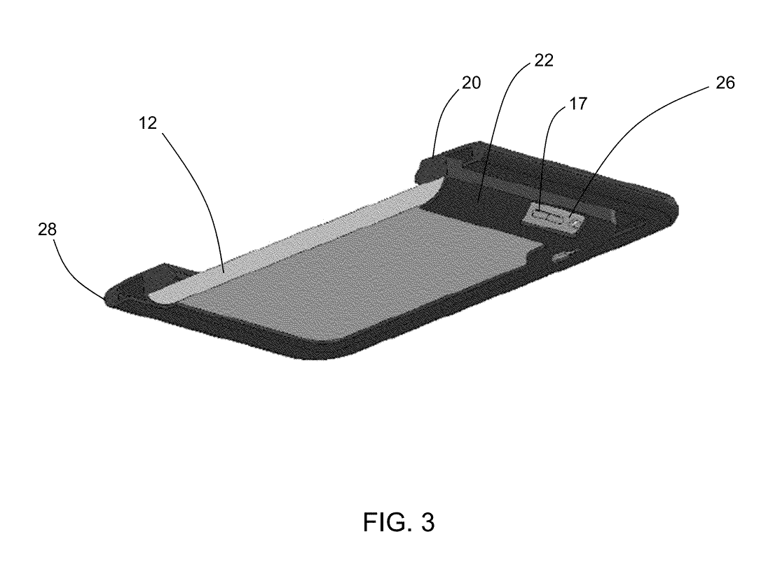

Some embodiments of elastomeric collar 20 are constructed to provide access to an IO port 17 of portable electronic device 12. FIG. 2 depicts an example of one such embodiment of elastomeric collar 20. FIG. 3 depicts the same embodiment of elastomeric collar 20 as that shown in FIG. 2 with a portable electronic device 12 engaged by elastomeric collar 20. As shown in FIG. 2, at least one embodiment of elastomeric collar 20 comprises openings 26 that align with IO port 17 (shown in FIG. 3) of portable electronic device 12. In this way, some embodiments of elastomeric collar 20 provide access to IO ports 17 while portable electronic device 12 is engaged by the elastomeric collar 20.

Some embodiments of elastomeric collar 20 include pads 25. In at least one embodiment, pads 25 are integral with elastomeric collar 20 and located on sleeve 22. In some embodiments, pads 25 provide an extra layer of cushioning by contacting protective tray 30 in advance of sleeve 22. In this way, pads 25 provide additional protection to the enclosed electronic device 12.

In at least one embodiment, sleeve 22 of elastomeric collar 20 captures and suspends the portable electronic device 12. In some embodiments, elastomeric collar 20 can be used independent of protective tray 30. That is to say, a portable electronic device 12 can be captured, suspended, and protected by elastomeric collar 20 alone, without the need to attach protective tray 30 to elastomeric collar 20.

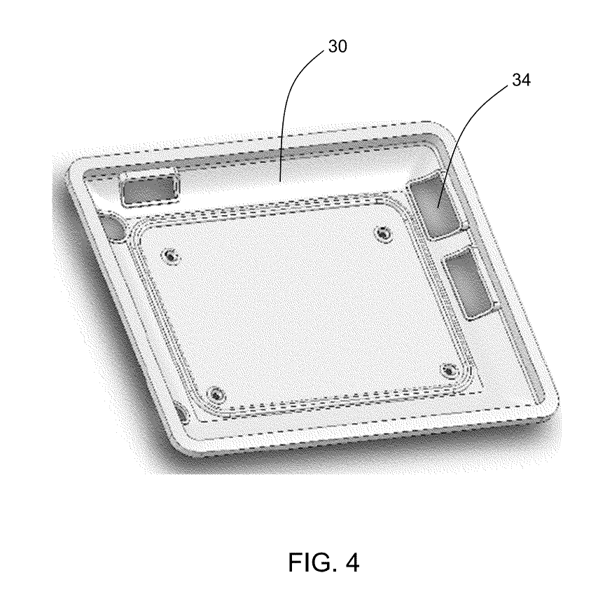

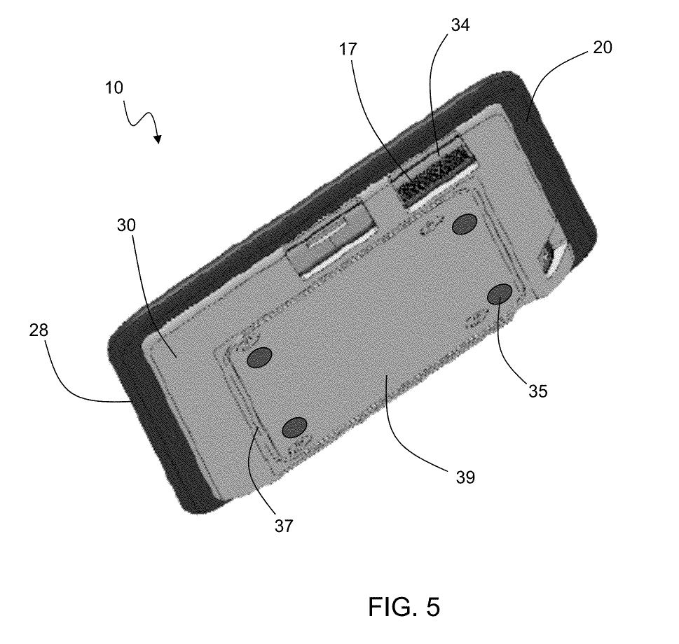

Similarly, some embodiments of protective tray 30 are constructed to provide access to an IO port 17 of portable electronic device 12. FIG. 4 depicts an example of one such embodiment of protective tray 30. As shown in FIG. 4, some embodiments of protective tray 30 include apertures 34 that align with IO port 17 (shown in FIG. 5) of portable electronic device 12.

FIG. 5 depicts an embodiment of protective tray 30 engaged by elastomeric collar 20 with a portable electronic device 12 enclosed therein. As shown in FIG. 5, aperture 34 of protective tray 30 aligns with IO port 17 of the portable electronic device 12 enclosed by protective cover assembly 10. In some embodiments, protective tray 30 includes aperatures 34 that enable the attachment of a strap (not shown) to protective tray 30. One embodiment of a strap attachment site is achieved by placing two apertures 34 in proximity to one another, with an intervening portion of protective tray 30 forming a bar between the two aperatures 34. A loop-ended strap can then be attached to the intervening portion of protective tray 30 by passing the strap loop around the intervening portion of the protective tray 30 and threading the rest of the strap through the loop. The other end of the loop-ended straps can include clips that allow the loop-ended straps to be attached to an intervening belt that connects the loop-ended straps to one another.

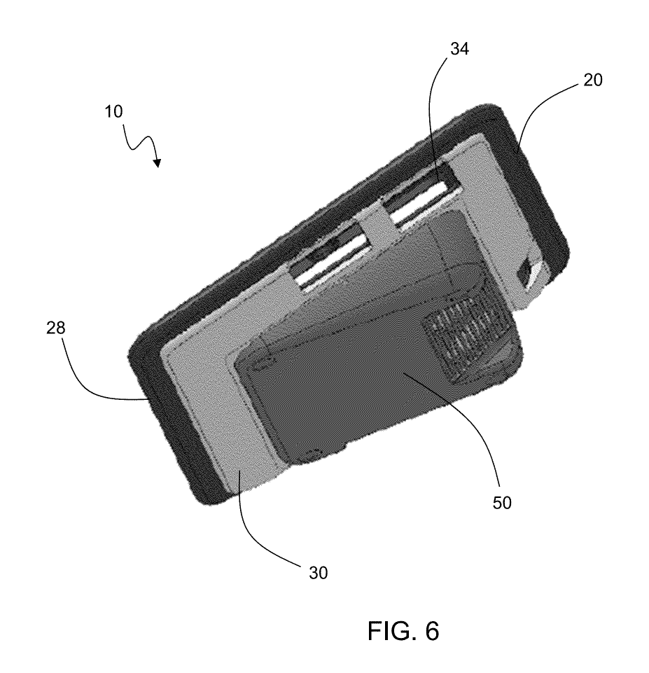

In some embodiments, protective tray 30 includes padded feet 35. Padded feet 35 provide an extra layer of cushioning to protective tray 30. Padded feet 35 also provide a frictional surface that resists sliding of protective assembly cover 10. In at least one embodiment, the exterior surface 39 of protective tray 30 includes a perimeter groove 37. Perimeter groove 37 facilitates the attachment of optional modules 50 (shown in FIG. 6). Perimeter groove 37 also helps to distribute any impact forces that are imparted to optional module 50. In this way, perimeter groove 37 helps protect the enclosed portable electronic device 12 from impact forces imparted onto an attached optional module 50.

Protective tray 30 is modular and easily adapted to many applications. As shown in FIG. 6, some embodiments of protective tray 30 are constructed to accommodate an optional module 50 that interfaces with the enclosed portable electronic device 12. A variety of optional modules 50 may be attached to protective tray 30. For example, optional module 50 could be a speaker assembly or a switch interface to allow single switches to operate the device as an alternative or in addition to the touch screen interface 14 of the portable electronic device 12. In another embodiment, optional module 50 is an infrared camera of use in environmental or industrial studies. In still another embodiment, optional module 50 is an additional battery or an extended life battery.

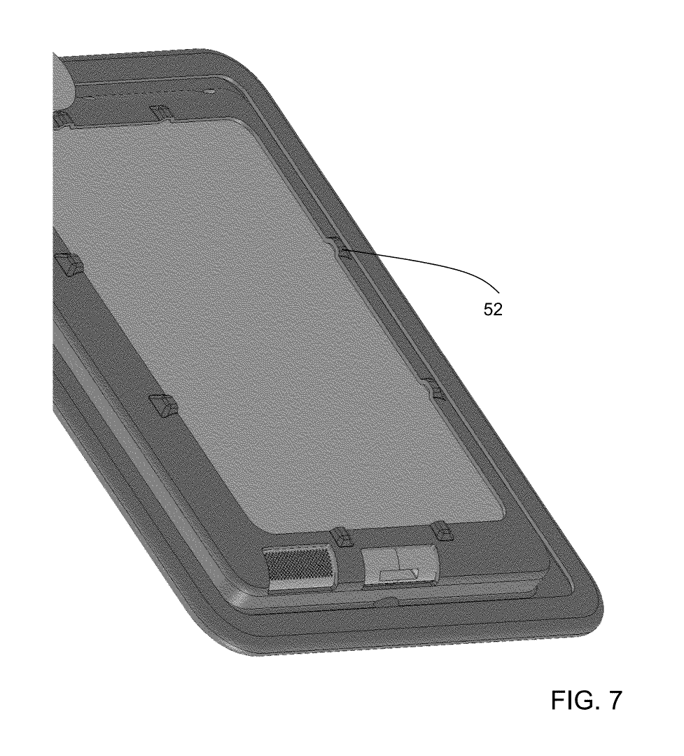

FIG. 7 is a bottom view of an embodiment showing the plurality of bumpers 52, which suspend the electronic device above the tray, and provide a cushioning effect upon impact. Although two bumpers per side are shown, any desired number of bumpers could be molded into the sleeve 22.

The above disclosure is intended to be illustrative and not exhaustive. The description will suggest many variations and alternatives to those of ordinary skill in the art. All of these alternatives and variations are intended to be included within the scope of the attached claims. Those familiar with the art many recognize other equivalents to the specific embodiments described herein which equivalents are also intended to be encompassed by the claims attached hereto.

1. A protective cover assembly, the assembly comprising:
a tray having a concave surface and a perimeter, the concave surface defining a volume sufficient to accommodate a portable electronic device; and
an elastomeric collar having an internal rim that reversibly engages and wraps around the perimeter of the tray.

2. The protective cover assembly of claim 1 wherein the elastomeric collar further comprises a sleeve, the sleeve being constructed and arranged to accommodate at least a portion of a perimeter edge of a portable electronic device.

3. The protective cover assembly of claim 1 further comprising a strap that reversibly attaches to the tray.

4. The protective cover assembly of claim 1 further comprising a keyguard, the keyguard having a lip region that engages the elastomeric collar.

5. The protective cover assembly of claim 4 wherein the elastomeric collar further comprises a plurality of detents that engage at least a portion of the lip region of the keyguard.

6. The protective cover assembly of claim 4 wherein the keyguard defines at least one opening.

7. The protective cover assembly of claim 4 wherein the keyguard is made of translucent plastic.

8. The protective cover assembly of claim 2 further comprising a module that attaches to the tray.

9. The protective cover assembly of claim 8 wherein the module is an audio speaker.

10. The protective cover assembly of claim 8 wherein the module is an infrared camera.

11. The protective cover assembly of claim 8 wherein the module is a battery.

12. A protective assembly comprising:
an elastomeric sleeve sufficiently dimensioned to stretch over a perimeter edge of a portable electronic device, the elastomeric sleeve capturing and suspending the portable electronic device; and
a perimeter portion circumferentially surrounding the elastomeric sleeve, wherein the perimeter portion is integral with the elastomeric sleeve.

13. The protective assembly of claim 12 further comprising a plurality of raised pads integrally attached to the elastomeric sleeve.

14. The protective assembly of claim 12 further comprising a tray having a concave surface and a rim, the concave surface defining a volume sufficient to accommodate a portable electronic device, the perimeter portion reversibly engaging and wrapping around the rim of the tray.
